(19) United States
(12) Patent Application Publication
(10) Pub. No.: US 2011/0249307 A1
(43) Pub. Date: Oct. 13, 2011

(54) HOLOGRAM AND ASSOCIATED METHODS OF FABRICATION THEREOF AND USE IN SECURITY/AUTHENTICATION APPLICATIONS

(75) Inventors: Brett Ronald Nelson, Logan, UT (US); Michael G. Fickes, Kennett Square, PA (US)

(73) Assignee: E. I. DU PONT DE NEMOURS AND COMPANY, Wilmington (DE)

(21) Appl. No.: 12/899,908

(22) Filed: Oct. 7, 2010

Related U.S. Application Data
(60) Provisional application No. 61/252,462, filed on Oct. 16, 2009.

(51) Int. Cl. G03H 1/02; G03F 7/20

(52) U.S. Cl. 359/2; 430/2

(57) ABSTRACT

A hologram (and related hologram element) contains and exhibits a holographic image when illuminated and viewed on angle and with the holographic image gradually fading when viewed increasingly off angle in 1^{st}-3^{rd} directions. This hologram also contains and exhibits a monochrome wash surface that obscures (partially or totally) the holographic image when viewed in a 4^{th} direction as the hologram is increasingly rotated off angle in a 4^{th} direction through a range of angles. The hologram can be fabricated with a variety of color choices for the monochrome wash surface. The hologram is useful in security and authentication applications and is used in a method provided herein for authentication of an article.

### CROSS REFERENCE TO RELATED APPLICATIONS

The present application claims the benefit of U.S. Provisional Application Ser. No. 61/252,462 filed on Oct. 16, 2009.

### FIELD OF THE INVENTION

This invention pertains to a hologram (and hologram element) that affords a distinctly different visual effect to an observer viewing the hologram as the observer tilts the hologram in a certain direction such that viewing of the hologram by the observer is increasingly off angle. This invention also pertains to an associated method of use of the hologram/hologram element in security and/or authentication applications and to a method for fabrication of the hologram/hologram element.

### BACKGROUND OF THE INVENTION

Holography is a form of optical information storage. The general principles are described in a number of references, e.g., “Photography by Laser” by E. N. Leith and J. Upatnieks in SCIENTIFIC AMERICAN, 212, No. 6, 24-35 (June, 1965). In brief, the object to be photographed or imaged is illuminated with collimated light, e.g., from a laser, and a light sensitive recording medium, e.g., a photographic plate, is positioned so as to receive light reflected from the object. Each point on the object reflects light to the entire recording medium, and each point on the medium receives light from the entire object. This beam of reflected light is known as the object beam. At the same time, a portion of the collimated light is beamed by a mirror directly to the medium, by-passing the object. This beam is known as the reference beam. What is recorded on the recording medium is the interference pattern that results from the interaction of the reference beam and the object beam impinging on the medium. When the processed recording medium is subsequently illuminated and observed appropriately, the light from the illuminating source is diffracted by the hologram to reproduce the wave-front that originally reached the medium from the object, so that the hologram resembles a window through which the virtual image of the object is observed in full three-dimensional form, complete with parallax.

Holograms that are formed by allowing the reference and object beams to enter the recording medium from the same side are known as transmission holograms and are also known as front beam holograms. Interaction of the object and reference beams in the recording medium forms fringes of material with varying refractive indices which are normal or near normal to the plane of the recording medium. When the hologram is played back by viewing with transmitted light, these fringes diffract the light to produce a viewable virtual image. Such transmission holograms may be produced by methods which are well known in the art, such as those disclosed in U.S. Pat. No. 3,506,327; U.S. Pat. No. 3,838,903 and U.S. Pat. No. 3,894,787.

Holograms formed by allowing the reference and object beams to enter the recording medium from opposite sides, so that they are traveling in approximately opposite directions, are known as reflection holograms and are also known as back beam holograms. Interaction of the object and reference beams in the recording medium forms fringes of material with varying refractive indices which are, approximately, planes parallel to the plane of the recording medium. When the hologram is played back these fringes act as mirrors reflecting incident light back to the viewer. Hence, the hologram is viewed in reflection rather than in transmission. Since the wavelength sensitivity of this type of hologram is very high, white light may be used for reconstruction. Reflection holograms produced by an off-axis process are disclosed in U.S. Pat. No. 3,532,406.

More and more, holograms as described above are being used as an enhanced security means attached to commercial products, such as digital optical disks, compact disks, batteries for electronic products, and any other products that may be susceptible to counterfeiting efforts. The use of a simple hologram(s) for identification and authentication purposes on such products is known. In the majority of references, such a hologram is a surface-relief hologram formed by a stamping process. This process may be incorporated into the manufacturing process of the product. There are disclosures of holograms (volume-phase hologram) being formed and applied to a product by way of a label. While using a simple hologram is advantageous for security devices, there is an increasingly significant drawback to this approach in that a simple hologram may be more easily counterfeited and applied to non-authentic counterfeited products as basic holographic technology becomes more widely known, widely practiced, and standardized. Therefore, such a holographic stamp or label bearing only a simple hologram has limited value as an authentication and/or security device.

There is a significant need for a holographic device that has unique features beyond those in a simple hologram and which consequently offers a higher level of security than that afforded by a simple hologram. The present invention provides a solution for this important need.

### SUMMARY OF THE INVENTION

An embodiment provides a volume reflection hologram comprising a holographic layer and affording a holographic image upon illumination, wherein:
a) the hologram when viewed on angle affords the holographic image having parallax;
b) the hologram when viewed increasingly off angle in a first direction, a second direction, and a third direction exhibits a decrease in brightness and visibility of the holographic image and the holographic image gradually fades away with the holographic layer appearing transparent as the hologram is tilted in each of these directions; and
c) the hologram when viewed increasingly off angle in a fourth direction exhibits an image of a monochrome surface which suddenly appears and at least partially masks the holographic image as the hologram is tilted increasingly in the fourth direction, said monochrome surface having a first color when viewed within a first range of viewing angles.

Another embodiment provides a holographic element comprising:

I) a volume reflection hologram comprising a holographic layer and affording a holographic image, wherein:
a) the hologram when viewed on angle affords the holographic image having parallax;
b) the hologram when viewed increasingly off angle in a first direction, a second direction, and a third direction exhibits a decrease in brightness and visibility of the holographic image and the holographic image gradually fades away with the holographic layer appearing transparent as the hologram is tilted increasingly in each of these directions; and
c) the hologram when viewed increasingly off angle in a fourth direction exhibits an image of a monochrome surface which suddenly appears and at least partially masks the holographic image as the hologram is tilted increasingly in the fourth direction, said monochrome surface having a first color when viewed within a first range of viewing angles; and
   II) a backing layer having a second color.

Yet another embodiment provides a method for establishing the authenticity of an article containing a hologram, said hologram comprising a holographic layer and affording a holographic image upon illumination, wherein:
i) the hologram when viewed on angle affords the holographic image having parallax;
ii) the hologram when viewed increasingly off angle in a first direction, a second direction, and a third direction exhibits a decrease in brightness and visibility of the holographic image and the holographic image gradually fades away with the holographic layer appearing transparent as the hologram is tilted in each of these directions; and
iii) the hologram when viewed increasingly off angle in a fourth direction exhibits an image of a monochrome surface suddenly appearing and at least partially masking the holographic image as the hologram is tilted increasingly in the fourth direction, said monochrome surface appearing and having a first color when viewed within a first range of viewing angles;
   said method comprising the steps of:

(a) providing the hologram on an article to be authenticated;

(b) illuminating the hologram with light from a light source having a center wavelength and a spectral bandwidth, wherein the spectral bandwidth of the light overlaps the spectral bandwidth of the hologram; and

(c) establishing the article bearing the hologram to be authentic only if the holographic image and the monochrome surface are observed or detected to behave as described in i), ii), and iii) for the 1^{st}-4^{th} viewing directions.

In an embodiment, the invention is a method of fabricating a color wash hologram, the method comprising the steps of:
a) creating a holographic H2 image of at least one object in a first photosensitive layer by holographic imaging at a first wavelength λ1 to give a first exposed layer;
b) creating a holographic H2 image of a diffuser in a second photosensitive layer by holographic imaging at a second wavelength λ2 to give a second exposed layer;
c) placing the first and second exposed layers in proximity to one another;
d) placing a third photosensitive layer in contact with either the first exposed layer or the second exposed layer;
e) exposing holographically the third photosensitive layer using a third wavelength λ3 through the first and second exposed layers to afford a third exposed layer containing the color wash hologram;
wherein λ1 and λ2 differ by at least 20 nanometers and λ3 lies between λ1 and λ2 and differs from λ1 by at least 5 nanometers.

### BRIEF DESCRIPTION OF THE DRAWINGS

FIG. 1 illustrates an XYZ coordinate system that is used to define plus and minus theta_{vertical} angles used in describing images and viewing effects seen by an observer in viewing the hologram and hologram element of this invention.

### DETAILED DESCRIPTION OF THE INVENTION

### Color Wash Hologram

In various embodiments (as described supra and in more detail below)), the invention is a volume reflection hologram, termed herein a color wash hologram, and a related hologram element.

In an embodiment, the first color of the volume reflection hologram is selected from the group consisting of red, gold, green, blue, and orange. In an embodiment, the first color is red. In an embodiment, the first color is gold. In an embodiment, the first color is green. In an embodiment, the first color is blue. In an embodiment, the first color is orange.

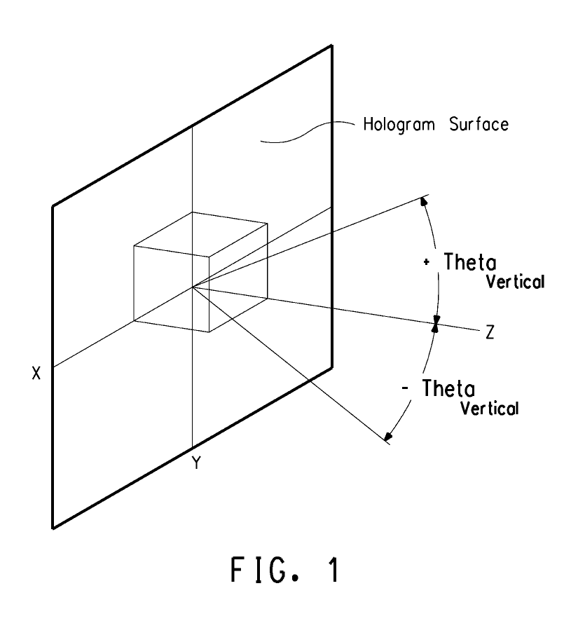

In an embodiment with reference to FIG. 1, a range of viewing angles of the volume reflection hologram for viewing the monochrome surface ranges from theta_{vertical}=(-alpha−5) degrees to theta_{vertical}=(-alpha+5) degrees when the hologram is illuminated from an angle of theta_{vertical}=+alpha degrees with alpha being an angle within a range of 0-90°. As one particular example, when the hologram is illuminated at an angle of +35 degrees, the range of viewing angles is from −30 degrees to −40 degrees. The monochrome surface having the first color is observed by an observer only over this range of 10 degrees of viewing angles. The appearance of the monochrome surface behaves as a specular reflection where the angle of incidence is equal to the angle of reflection at its midpoint within the angular range of 10 degrees. The monochrome surface appears though to be due to holographic diffraction and not due to reflection by a mirror.

### Color Wash Holographic Element

In various embodiments, a holographic element is provided as described above.

In an embodiment, the first color of the holographic element is selected from the group consisting of red, gold, green, blue, and orange. In an embodiment the first color is red. In an embodiment, the first color is gold. In an embodiment, the first color is green. In an embodiment, the first color is blue. In an embodiment, the first color is orange.

In an embodiment, the second color of the holographic element is selected from the group consisting of black, brown, gray, red, gold, green, blue, and orange. In yet another embodiment, the second color is black.

In an embodiment with reference to FIG. 1, a range of viewing angles of the hologram element for viewing the monochrome surface ranges from theta_{vertical}=(-alpha−5) degrees to theta_{vertical}=(-alpha+5) degrees when the hologram element is illuminated from an angle of theta_{vertical}=+alpha degrees with alpha being an angle within a range of 0-90°. As one particular example, when the hologram is illuminated at an angle of +35 degrees, the range of viewing angles is from −30 degrees to −40 degrees. The monochrome surface having the first color is observed by an observer only over this range of 10 degrees of viewing angles.

### Method of Establishing Authenticity Using Hologram or Hologram Element

Various embodiments provide a method for establishing the authenticity of an article containing a hologram as described above.

In an embodiment of the method, the holographic element as described above is used in place of the hologram, wherein the holographic element eventually has the appearance of a monochrome surface corresponding to the color of the backing as the hologram is viewed increasingly off angle for each of the 1^{st}-4^{th} viewing directions. In one particular embodiment, the color of the backing is black.

### Method of Fabrication of a Color Wash Hologram

As explained above, this method entails creating a H2 holographic image of at least one object in a first photosensitive layer and a H2 holographic image of a diffuser in a second photosensitive layer to afford two H2 master holograms and then using these master holograms to replicate the object and diffuser images in a third photosensitive layer. With regard to this method, first and second exposed layers are created in steps a) and b) of this method. Then in step c), the first and second exposed layers are placed in proximity to one another. By being in proximity to one another, the first and second layers can be in direct contact with one another but not bonded together and preferably with a refractive index matching fluid being present on outer surfaces where these two layers contact each other. Alternatively, the first and second layers can be bonded to each other, preferably with an optical adhesive whose refractive index is close to that of the exposed first and second layers. Holographic replication is then carried out in steps d) and e) (see above) using a third photosensitive layer to afford a color wash hologram (H3 hologram having a H3 image of the monochrome wash color). As explained below, holographic replication is done in a usual manner except that the replication wavelength is set to be between the dominant response wavelengths of the label (object) and the diffuser.

The first and second photosensitive layers are preferably dichromated gelatin. Dichromated gelatin is advantageous as photosensitive material for use in preparing master holograms, since it has a wide optical bandwidth. For example, a master with a 476 nm dominant wavelength for reflection will still reflect light at other nearby wavelengths, albeit at a much lesser intensity. Consequently, a H2 master with an intended wavelength for replication of 476 nm may still be replicated at 488 nm as the latter wavelength is still close to the intended replication wavelength of 476 nm. The nearer the replication wavelength is to the intended wavelength, the more the resulting image that is replicated will resemble the intended image.

On the other hand, when photopolymer is imaged at a wavelength that is further from the H2 master intended wavelength, the on-angle label decreases in efficiency as the master is now reflecting light that is further toward the edges of its optical bandwidth.

While not being bound by theory, the inventor(s) offer the following explanation for explaining the phenomenon of the color wash hologram. The H2 master that is being used has a second layer in the form of a diffuser. As the replication wavelength becomes more distant from the intended object (e.g., label) wavelength, it subsequently becomes closer to the diffuser wavelength, which also has a relatively wide optical bandwidth. If the replication wavelength were to match the diffuser wavelength, then the result would simply be an HOE reflector. However, the replication wavelength is positioned somewhere between the two intended wavelengths, so that feedback results from the outer edges of the bandwidth from both master layers (object and diffuser). Because the replication wavelength is positioned much closer to the label layer wavelength, the result is an on-angle image that closely resembles the normal photopolymer hologram. However, the unintended reflections from both layers are now interfering with each other, creating a spectral reflection on the surface of the photopolymer. The resulting wavelength can be controlled by adjusting the replication wavelength, understanding that this wavelength must be nearer to the intended image and further from the unintended image.

The H2 masters of an image and of a diffuser that are used in replication according to the invention can be individual masters that are placed proximate to each other during execution of the method of fabrication or these two H2 masters can be glued together to form one piece using an adhesive, preferably one that is of optical quality. If an adhesive is not used, it is preferred that the two H2 masters be optically coupled with a liquid having approximately the same refractive index as the two H2 masters.

In the replication step of the method of forming a color wash hologram according to the invention, a photosensitive material is used as recording material to create a replicate. Use of a photopolymer photosensitive film, such as a holographic recording film, is preferred.

In this method of fabrication of a color wash hologram, the wavelength (λ3, Repl λ) used in the replication step should be between the wavelength of response of the holographic image (λ1, Label λ in Table 1) and the wavelength of response of the diffuser (λ2, Diffuser λ in Table 1). Preferably, λ1 (label λ) is closer to λ3 (Repl λ) than λ3 (Repl λ) is to λ2 (Diffuser λ). In an embodiment, the absolute value of (λ3−λ1) is less than absolute value of (λ2−λ3). In an embodiment, (λ3−λ1) is less than (λ2−λ3). In various embodiments, (λ3−λ1) ranges from about 5 nm to about 35 nm, from about 10 nm to about 30 nm, from about 12 nm to about 45 nm, and from about 12 to about 26 nm. In various embodiments, (λ2−λ3) ranges from about 25 nm to about 50 nm, from about 30 nm to about 47 nm, from about 30 nm to about 45 nm, and from about 36 to about 44 nm.

There are basically two kinds of (off/on) angles commonly used in holography. One kind is in regard to illumination of a hologram or a reference angle of a hologram. The other kind is in regard to the most favorable viewing angles (measured eye of observer to center of the hologram being viewed from its front face). For purposes of this patent application, these terms (off angle and on angle) are with respect to the most favorable viewing angles.

A pyramidal shaped cone-viewing zone defines the most favorable viewing angles when a hologram is ideally illuminated. Ideal illumination is typically with a near collimated white or monochromatic light source pointing at the center of the hologram from approximately its reference angle (which is usually positive). For the volume phase holograms described herein, this pyramidal shaped cone-viewing zone is approximately plus/minus 30 degrees left to right and approximately plus/minus 20 degrees up to down from an optimum viewing angle, which is at or near (within 5 degrees) of a front normal line of the hologram.

Angles within the above pyramidal shaped cone-viewing zone are defined to be “on angle” and angles outside the above pyramidal shaped cone-viewing zone are defined to be “off angle”.

### GLOSSARY

H1 and H2 Holograms—These terms are well-known in holography and are used herein according to their standard textbook definitions. They are described in many references on holography, such as, for example, in Practical Holography (3^{rd} Edition) by Graham Saxby (2004). See, in particular, Chapter 9, Bypass Holograms and especially page 124, FIG. 9.4.
H3 Hologram—This term is also well-known in holography and is used herein according to its standard textbook definition. An H3 hologram is a replicate of a H2 hologram or master hologram.
HRF—Holographic recording film, which is a photosensitive (for example, a photopolymer) film used to record holograms within the film using holographic imaging.
Parallax—An apparent change in the position of an object resulting from a change in position of an observer viewing the object.
Reference Angle of a Hologram—This angle is a positive number when an object is holographically imaged for viewing on its left side and has a left-sided perspective and is a negative number when an object is holographically imaged for viewing on its right side and has a right-sided perspective. This angle is dependent upon the angular relationship (with respect to a normal line) of a coherent beam of reference light being used to holographically expose a photosensitive film (e.g., HRF) to produce the hologram. More specifically, this angle is the angle, expressed as either a negative number or positive number, that the reference beam of light makes with respect to a normal line of the photosensitive film. As one example, if holographic imaging is done such that the reference beam of light makes an angle of 30 degrees with respect to normal and affords an image of an object for viewing on its left side, then the reference angle in this case is plus (+) 30 degrees.

### EXAMPLES

A vibration isolated optical table equipped with one of two stable metal mounts (depending upon whether an H1 or H2 was being produced) was used for holographic imaging in these examples. The mount in use held a fresh, unexposed dichromated gelatin (DCG) coated glass plate (future H1 or H2) prior to each holographic exposure. Dichromated gelatin (DCG) is a common holographic recording material that is described in numerous references. See, for example, “Control of DCG and non silver holographic materials” by Rallison at the following website: http://www.xmission.com/˜ralcon/dcgprocess/p1.html.

Table 1 gives a summary of key experimental conditions and results for thirteen examples that are presented below.

TABLE 1

| | Label λ | Diffuser λ | Repl λ | Imaging | H3 | | Approximate Wash |
|---|---|---|---|---|---|---|---|
| | (nm) | (nm) | (nm) | Angle^{a} | Hologram | Monochrome | Wavelength Range^{c} |
| Example | (λ1) | (λ2) | (λ3) | (degrees) | Color^{b} | Wash Color | (nm) |
| 1 | 476 | 532 | 488 | 35 | Gold | Red | 620-640 |
| 2 | 488 | 550 | 514 | 35 | Orange-Gold | Red | 630-650 |
| 3 | 459 | 514 | 476 | 35 | Green | Green | 540-560 |
| 4 | 476 | 532 | 488 | 45 | Gold | Deep Red | 660-680 |
| 5 | 488 | 550 | 514 | 45 | Orange-Gold | Deep Red | 670-690 |
| 6 | 459 | 514 | 476 | 45 | Green | Gold | 570-590 |
| 7 | 476 | 532 | 488 | 30 | Gold | Orange-Red | 600-620 |
| 8 | 488 | 550 | 514 | 30 | Orange-Gold | Red-Orange | 610-630 |
| 9 | 459 | 514 | 476 | 30 | Green | Green | 530-550 |
| 10 | 476 | 532 | 488 | 40 | Gold | Red | 640-660 |
| 11 | 488 | 550 | 514 | 40 | Orange-Gold | Deep Red | 650-670 |
| 12 | 459 | 514 | 476 | 40 | Green | Green | 550-570 |
| 13 | 413 | 488 | 458 | 35 | Green | Blue | 450-480 |

^{a}All imaging angle values for the examples shown above were positive numbers.
^{b}Colors of the H3 holograms reported in this table are for the holograms after color tuning.
^{c}Approximate wavelength ranges were derived through side-by-side comparison to a photonic spectrum reference chart and are meant to suggest an approximate value for the dominant wavelength of the color wash.

### Example 1

Mastering

A H2 master of an Izon®¹ label was made using dichromated gelatin that was imaged and processed for 476 nm replication. ¹Izon® is a registered trademark of E.I. DuPont de Nemours and Company.

A H2 master of a holographic diffuse reflector was also made using dichromated gelatin that was imaged and processed for 532 nm replication. This H2 master was made in the same general manner as the above H2 master except that a diffuse reflector was used in place of a 3-D model in holographic imaging to produce this H2 master.

The above two H2 masters were combined together using an UV curable optical adhesive to afford a multilayer H2 master.

Imaging

The multilayer H2 master was then placed at +35 degrees (angle being within YZ plane) off normal (see FIG. 1; Y axis is in the vertical direction and Z is a normal line as shown if FIG. 1) in a holographic film replicator. HRF 734 holographic film (E.I. DuPont de Nemours, Wilmington, Del.) was used for holographic replication. A replicator (E.I. DuPont de Nemours, Wilmington, Del.) was used in replication. (Other commercial holographic films and any other contact copy replicator can be used instead of those listed above.) The replicator was operated using a single laser that was adjusted to provide its light output at 488 nm. This step resulted in a replicate (H3) of the H2 master being produced in the photopolymer film using standard replication technology with the one exception being that the laser was operated at 488 nm instead of 476 nm. The H3 hologram that resulted was gold when viewed in ordinary room light.

Tuning

CTF146 color tuning film (E.I. DuPont de Nemours, Wilmington, Del.) was laminated at 100° C. to the H3 hologram layer that resulted upon imaging. The resulting CTF/H3 laminate was heated in an oven operated at 150° F. for 7.5 minutes and was subsequently allowed to cool in an air stream while being passed under a UV bank. This processing afforded a color-tuned H3 hologram. (This color tuning processing was done as described in U.S. Pat. No. 4,959,283.)

Conversion

A black ink was applied to a back face of the color-tuned H3 hologram upon completion of the above tuning step to afford a black backing layer. A clear topcoat was also applied using a web application to the front face of the H3 hologram layer to afford a clear 1 mil thick topcoat. Execution of these two steps resulted in the color-tuned H3 hologram being converted to a hologram element.

### Testing

After the above processing was done, the hologram element produced when viewed off angle in a fourth direction with (noncoherent) room lighting resulted in a monochrome surface suddenly appearing that was red in coloration as the hologram element was increasingly rotated about the x axis to larger positive theta_{vertical} angles with respect to an observer viewing the hologram element from the normal direction. (Rotation to larger positive theta_{vertical} angles corresponds to rotation about the X axis such that the top of the hologram moves further away from an observer viewing it head-on and the bottom of the hologram moves closer to the observer.) See FIG. 1 for an explanation of the coordinate system defining angles and axes. Once the red monochrome surface appeared, it only remained for increasing theta_{vertical} (rotation) angles of approximately 10 degrees of the angular value where it was first observed. Rotations beyond this maximum angular value in the fourth direction then suddenly afforded a gold color (tuned H3 hologram color) reappearing and thence a black color (of the backing material). Rotations in the minus theta_{vertical} direction about the x axis as well as left and right about the y axis with respect to an observer viewing from normal (these rotations correspond to the first-third directions) did not afford a sudden red monochrome surface but only afforded a gold monochrome surface that gradually faded and then went to black (color of the backing material) at very large off angle values.

With regard to FIG. 1, an outer surface of the hologram is in the X-Y plane. The rectangular solid in FIG. 1 is present to indicate that a standard XYZ coordinate system is applicable with all three axes being orthogonal to each other and that this FIGURE has a left-handed perspective.

The monochrome color as described above that suddenly appears with rotation in a fourth direction is termed the monochrome wash color, as it has the effect of partially or completely washing out the previously existing holographic model. The monochrome wash color in this example was observed to be red and was characterized to have an approximate wash wavelength range of 620-640 nanometers.

### Example 2

Mastering

A H2 master of an Izon®¹ label was made using dichromated gelatin that was imaged and processed for 488 nm replication.

A H2 master of a holographic diffuse reflector was also made using dichromated gelatin that was imaged and processed for 550 nm replication. This H2 master was made in the same general manner as the above H2 master except that a diffuse reflector was used in place of a 3-D model in holographic imaging to produce this H2 master.

The above two H2 masters were combined together using an UV curable optical adhesive to afford a multilayer H2 master.

Imaging

The multilayer H2 master was then placed at +35 degrees (angle being within YZ plane) off normal (see FIG. 1; Y axis is in the vertical direction and Z is a normal line as shown if FIG. 1) in a holographic film replicator. HRF 734 holographic film (E.I. DuPont de Nemours, Wilmington, Del.) was used for holographic replication. A replicator (E.I. DuPont de Nemours, Wilmington, Del.) was used in replication. (Other commercial holographic films and any other contact copy replicator can be used instead of those listed above.) The replicator was operated using a single laser that was adjusted to provide its light output at 514 nm. This step resulted in a replicate (H3) of the H2 master being produced in the photopolymer film using standard replication technology with the one exception being that the laser was operated at 514 nm instead of 488 nm. The H3 hologram that resulted was orange-gold when viewed in ordinary room light.

Tuning

Tuning was identical to that described in Example 1.

Conversion

Conversion was identical to that described in Example 1.

Testing

The hologram element produced characteristics identical to those observed in Example 1, except that, while the monochrome wash color that suddenly appeared in this example was observed to be red (as in Example 1), it was characterized to have an approximate wash wavelength range of 630-650 nanometers (instead of 620-640 nm as in Example 1), and the re-appearing color was orange-gold (H3 hologram color after color tuning). See Table 1.

### Example 3

Mastering

A H2 master of an Izon®¹ label was made using dichromated gelatin that was imaged and processed for 459 nm replication.

A H2 master of a holographic diffuse reflector was also made using dichromated gelatin that was imaged and processed for 514 nm replication. This H2 master was made in the same general manner as the above H2 master except that a diffuse reflector was used in place of a 3-D model in holographic imaging to produce this H2 master.

The above two H2 masters were combined together using an UV curable optical adhesive to afford a multilayer H2 master.

Imaging

The multilayer H2 master was then placed at +35 degrees (angle being within YZ plane) off normal (see FIG. 1; Y axis is in the vertical direction and Z is a normal line as shown if FIG. 1) in a holographic film replicator. HRF 734 holographic film (E.I. DuPont de Nemours, Wilmington, Del.) was used for holographic replication. A replicator (E.I. DuPont de Nemours, Wilmington, Del.) was used in replication. (Other commercial holographic films and any other contact copy replicator can be used instead of those listed above.) The replicator was operated using a single laser that was adjusted to provide its light output at 476 nm. This step resulted in a replicate (H3) of the H2 master being produced in the photopolymer film using standard replication technology with the one exception being that the laser was operated at 476 nm instead of 459 nm. The H3 hologram that resulted was green when viewed in ordinary room light.

Tuning

Tuning was identical to that described in Example 1.

Conversion

Conversion was identical to that described in Example 1.

Testing

The hologram element produced characteristics identical to those observed in Example 1, except that the monochrome wash color that suddenly appeared was observed to be green and was characterized to have an approximate wash wavelength range of 540-560 nanometers, and the re-appearing color was green (H3 hologram color after color tuning).

### Example 4

Mastering

A mastering process identical to that in Example 1 was used.

Imaging

An imaging process identical to that in Example 1 was used except that the multilayer H2 master was placed at +45 degrees off normal (instead of +35 degrees as in Example 1). The H3 hologram that resulted was gold when viewed in ordinary room light.

Tuning

Tuning was identical to that described in Example 1.

Conversion

Conversion was identical to that described in Example 1.

Testing

The hologram element produced characteristics identical to those observed in Example 1, except that the monochrome wash color that suddenly appeared in this example was observed to be a deep red (deeper, more intense red than in Example 1) and was characterized to have an approximate wash wavelength range of 660-680 nanometers, and the re-appearing color was gold (H3 hologram color after color tuning).

### Example 5

Mastering

A mastering process identical to that in Example 2 was used.

Imaging

An imaging process identical to that in Example 2 was used except that the multilayer H2 master was placed at +45 degrees off normal (instead of +35 degrees as in Example 2). The H3 hologram that resulted was orange-gold when viewed in ordinary room light.

Tuning

Tuning was identical to that described in Example 1.

Conversion

Conversion was identical to that described in Example 1.

Testing

The hologram element produced characteristics identical to those observed in Example 2, except that the monochrome wash color that suddenly appeared in this example was observed to be a deep red (deeper, more intense red than in Example 2) and was characterized to have an approximate wash wavelength range of 670-690 nanometers, and the re-appearing color was orange-gold (H3 hologram color after color tuning).

### Example 6

Mastering

A mastering process identical to that in Example 3 was used.

Imaging

An imaging process identical to that in Example 3 was used except that the multilayer H2 master was placed at +45 degrees off normal (instead of +35 degrees as in Example 3). The H3 hologram that resulted was green when viewed in ordinary room light.

Tuning

Tuning was identical to that described in Example 1.

Conversion

Conversion was identical to that described in Example 1.

Testing

The hologram element produced characteristics identical to those observed in Example 3, except that the monochrome wash color that suddenly appeared in this example was observed to be gold and was characterized to have an approximate wash wavelength range of 570-590 nanometers, and the re-appearing color was green (H3 hologram color after color tuning).

### Example 7

Mastering

A mastering process identical to that in Example 1 was used.

Imaging

An imaging process identical to that in Example 1 was used except that the multilayer H2 master was placed at +30 degrees off normal (instead of +35 degrees as in Example 1). The H3 hologram that resulted was gold when viewed in ordinary room light.

Tuning

Tuning was identical to that described in Example 1.

Conversion

Conversion was identical to that described in Example 1.

Testing

The hologram element produced characteristics identical to those observed in Example 1, except that the monochrome wash color that suddenly appeared in this example was observed to be orange-red (more of an orange color and less red compared to Example 8 below) and was characterized to have an approximate wash wavelength range of 600-620 nanometers, and the re-appearing color was gold (H3 hologram color after color tuning).

### Example 8

Mastering

A mastering process identical to that in Example 2 was used.

Imaging

An imaging process identical to that in Example 2 was used except that the multilayer H2 master was placed at +30 degrees off normal (instead of +35 degrees as in Example 2). The H3 hologram that resulted was orange-gold when viewed in ordinary room light.

Tuning

Tuning was identical to that described in Example 1.

Conversion

Conversion was identical to that described in Example 1.

Testing

The hologram element produced characteristics identical to those observed in Example 2, except that the monochrome wash color that suddenly appeared in this example was observed to be a red-orange (more red and less orange compared to Example 7) and was characterized to have an approximate wash wavelength range of 610-630 nanometers, and the re-appearing color was orange-gold (H3 hologram color after color tuning).

### Example 9

Mastering

A mastering process identical to that in Example 3 was used.

Imaging

An imaging process identical to that in Example 3 was used except that the multilayer H2 master was placed at +30 degrees off normal (instead of +35 degrees as in Example 3). The H3 hologram that resulted was green when viewed in ordinary room light.

Tuning

Tuning was identical to that described in Example 1.

Conversion

Conversion was identical to that described in Example 1.

Testing

The hologram element produced characteristics identical to those observed in Example 3, except that the monochrome wash color (green) was characterized to have an approximate wash wavelength range of 530-550 nanometers, and the re-appearing color was green (H3 hologram color after color tuning).

### Example 10

Mastering

A mastering process identical to that in Example 1 was used.

Imaging

An imaging process identical to that in Example 1 was used except that the multilayer H2 master was placed at +40 degrees off normal (instead of +35 degrees as in Example 1). The H3 hologram that resulted was gold when viewed in ordinary room light.

Tuning

Tuning was identical to that described in Example 1.

Conversion

Conversion was identical to that described in Example 1.

Testing

The hologram element produced characteristics identical to those observed in Example 7, except that the monochrome wash color that suddenly appeared in this example was observed to be red (instead of orange-red as in Example 7) and was characterized to have an approximate wash wavelength range of 640-660 nanometers, and the re-appearing color was gold (H3 hologram color after color tuning).

### Example 11

Mastering

A mastering process identical to that in Example 2 was used.

Imaging

An imaging process identical to that in Example 2 was used except that the multilayer H2 master was placed at +40 degrees off normal (instead of +35 degrees as in Example 2). The H3 hologram that resulted was orange-gold when viewed in ordinary room light.

Tuning

Tuning was identical to that described in Example 1.

Conversion

Conversion was identical to that described in Example 1.

Testing

The hologram element produced characteristics identical to those observed in Example 8, except that the monochrome wash color that suddenly appeared in this example was observed to be a deep red (rather than red-orange as in Example 8) and was characterized to have an approximate wash wavelength range of 650-670 nanometers, and the re-appearing color was orange-gold (H3 hologram color after color tuning).

### Example 12

Mastering

A mastering process identical to that in Example 3 was used.

Imaging

An imaging process identical to that in Example 3 was used except that the multilayer H2 master was placed at +40 degrees off normal (instead of +35 degrees as in Example 3). The H3 hologram that resulted was green when viewed in ordinary room light.

Tuning

Tuning was identical to that described in Example 1.

Conversion

Conversion was identical to that described in Example 1.

Testing

The hologram element produced characteristics identical to those observed in Example 3, except that the monochrome wash color (green) was characterized to have an approximate wash wavelength range of 550-570 nanometers, and the re-appearing color was green (H3 hologram color after color tuning).

### Example 13

### Prophetic

Mastering

A H2 master of an Izon®¹ label is made using dichromated gelatin that is imaged and processed for 413 nm replication.

A H2 master of a holographic diffuse reflector is also made using dichromated gelatin that is imaged and processed for 488 nm replication. This H2 master is made in the same general manner as the above H2 master except that a diffuse reflector is used in place of a 3-D model in holographic imaging to produce this H2 master.

The above two H2 masters are combined together using an UV curable optical adhesive to afford a multilayer H2 master.

Imaging

The multilayer H2 master is then placed at +35 degrees (angle being within YZ plane) off normal (see FIG. 1; Y axis is in the vertical direction and Z is a normal line as shown if FIG. 1) in a holographic film replicator. HRF 734 holographic film (E.I. DuPont de Nemours, Wilmington, Del.) is used for holographic replication. A replicator (E.I. DuPont de Nemours, Wilmington, Del.) is used in replication. The replicator is operated using a single laser that was adjusted to provide its light output at 458 nm. This step results in a replicate (H3) of the H2 master being produced in the photopolymer film using standard replication technology with the one exception being that the laser is operated at 476 nm instead of 459 nm. The H3 hologram that results is green when viewed in ordinary room light.

Tuning

CTF146 color tuning film (E.I. DuPont de Nemours, Wilmington, Del.) is laminated at 100° C. to the H3 hologram layer that results upon imaging. The resulting CTF/H3 laminate is heated in an oven operated at 150° F. for 7.5 minutes and is subsequently allowed to cool in an air stream while being passed under a UV bank. This processing affords a color-tuned H3 hologram. (This color tuning processing is done as described in U.S. Pat. No. 4,959,283.)

Conversion

A black ink is applied to a back face of the color-tuned H3 hologram upon completion of the above tuning step to afford a black backing layer. A clear topcoat is also applied using a web application to the front face of the H3 hologram layer to afford a clear 1 mil thick topcoat. Execution of these two steps results in the color-tuned H3 hologram being converted to a hologram element.

### Testing

After the above processing is done, the hologram element produced when viewed off angle in a fourth direction with (noncoherent) room lighting is prophesized to result in a monochrome surface suddenly appearing that is blue in coloration as the hologram element is increasingly rotated about the x axis to larger positive theta_{vertical} angles with respect to an observer viewing the hologram element from the normal direction. (Rotation to larger positive theta_{vertical} angles corresponds to rotation about the X axis such that the top of the hologram moves further away from an observer viewing it head-on and the bottom of the hologram moves closer to the observer.) See FIG. 1 for an explanation of the coordinate system defining angles and axes. Once the blue monochrome surface appears, it is prophesized to only remain when the theta_{vertical} angle is within approximately plus or minus 5 degrees of the angular value where it is first observed. Rotations beyond this maximum angular value in the fourth direction then suddenly afford a green color reappearing. Rotations in the minus theta_{vertical} direction about the x axis as well as left and right about the y axis with respect to an observer viewing from normal (these rotations correspond to the first-third directions) did not afford a sudden blue monochrome surface but only afforded a green monochrome surface that gradually fades and then goes to black (color of the backing material) at very large off angle values. The monochrome wash color in this example is prophesized to be blue and furthermore prophesized to exhibit an approximate wash wavelength range of 450-480 nanometers.

### Example 14

### Comparative and Prophetic

The procedures (mastering, imaging, tuning, conversion, and testing) as described in Example 1 are repeated as indicated for Example 1 except that the initial H2 master contains no image (instead of an image of an Izon®¹ label as in Example 1). It is prophesized that, upon testing, the resulting H3 hologram element does not exhibit any color wash effect as found for the hologram elements of inventive Examples 1-13.

### Example 15

### Comparative and Prophetic

The procedures (mastering, imaging, tuning, conversion, and testing) as described in Example 1 are repeated as indicated for Example 1 except that the H2 master of a holographic diffuse reflector is absent and is replaced with a blank master containing no image. It is prophesized that, upon testing, the resulting H3 hologram element does not exhibit any color wash effect as found for the hologram elements of inventive Examples 1-13.

### Example 16

### Comparative and Prophetic

The procedures (mastering, imaging, tuning, conversion, and testing) as described in Example 1 are repeated as indicated for Example 1 except that the master used in replication is a single layer H2 master of an Izon®¹ label (without a second layer of a holographic diffuse reflector master being present). It is prophesized that, upon testing, the resulting H3 hologram element does not exhibit any color wash effect as found for the hologram elements of inventive Examples 1-13.

### Example 17

### Comparative and Prophetic

The procedures (mastering, imaging, tuning, conversion, and testing) as described in Example 1 are repeated as indicated for Example 1 except that the master used in replication is a single layer H2 master of a holographic diffuse reflector (without a second layer of an Izon®¹ label master being present). It is prophesized that, upon testing, the resulting H3 hologram element does not exhibit any color wash effect as found for the hologram elements of inventive Examples 1-13.

### Example 18

### Comparative and Prophetic

The procedures (mastering, imaging, tuning, conversion, and testing) as described in Example 1 are repeated as indicated for Example 1 except that the replication wavelength is 476 nm (same wavelength used for imaging the label) instead of 488 nm. It is prophesized that, upon testing, the resulting H3 hologram element does not exhibit any color wash effect as found for the hologram elements of inventive Examples 1-13.

### Example 19

### Prophetic

The procedures (mastering, imaging, tuning, conversion, and testing) as described in Example 1 are repeated as indicated for Example 1 except that the label wavelength is 532 nm (instead of 476 nm), the diffuser wavelength is 476 nm (instead of 532 nm), and the replication wavelength is 520 nm (instead of 488 nm). It is prophesized that, upon testing, the resulting H3 hologram element does exhibit a color wash effect as similar to those effects found for the hologram elements of inventive Examples 1-13.

What is claimed is:

1. A volume reflection hologram comprising a holographic layer and affording a holographic image upon illumination, wherein:
a) the hologram when viewed on angle affords the holographic image having parallax;
b) the hologram when viewed increasingly off angle in a first direction, a second direction, and a third direction exhibits a decrease in brightness and visibility of the holographic image and the holographic image gradually fades away with the holographic layer appearing transparent as the hologram is tilted in each of these directions; and
c) the hologram when viewed increasingly off angle in a fourth direction results in a monochrome surface which suddenly appears and at least partially masks the holographic image as the hologram is tilted increasingly in the fourth direction, said monochrome surface having a first color when viewed within a range of viewing angles.

2. The volume reflection hologram of claim 1 wherein the first color is selected from the group consisting of red, gold, green, blue, and orange.

3. The volume reflection hologram of claim 2 wherein the first color is red.

4. The volume reflection hologram of claim 1 wherein the range of viewing angles of the monochrome surface ranges from theta_{vertical}=(-alpha−5) degrees to theta_{vertical}=(-alpha+5) degrees when the hologram is illuminated from an angle of theta_{vertical}=+alpha degrees with alpha being an angle within a range of 0-90°.

5. A holographic element comprising:
I) a volume reflection hologram comprising a holographic layer and affording a holographic image, wherein:
a) the hologram when viewed on angle affords the holographic image having parallax;
b) the hologram when viewed increasingly off angle in a first direction, a second direction, and a third direction exhibits a decrease in brightness and visibility of the holographic image and the holographic image gradually fades away with the holographic layer appearing transparent as the hologram is tilted increasingly in each of these directions; and
c) the hologram when viewed increasingly off angle in a fourth direction results in a monochrome surface which suddenly appears and at least partially masks the holographic image as the hologram is tilted increasingly in the fourth direction, said monochrome surface having a first color when viewed within a first range of viewing angles; and
II) a backing layer having a second color.

6. The holographic element of claim 5 wherein the first color is selected from the group consisting of red, gold, green, blue, and orange.

7. The holographic element of claim 6 wherein the first color is red.

8. The holographic element of claim 7 wherein the second color is selected from the group consisting of black, brown, gray, red, gold, green, blue, and orange.

9. The holographic element of claim 8 wherein the second color is black.

10. The holographic element of claim 5 wherein the first range of viewing angles of the monochrome surface ranges from theta_{vertical}=(-alpha−5) degrees to theta_{vertical}=(-alpha+5) degrees when the hologram is illuminated from an angle of theta_{vertical}=+alpha degrees with alpha being an angle within a range of 0-90°.

11. A method for establishing the authenticity of an article containing a hologram, said hologram comprising a holographic layer and affording a holographic image upon illumination, wherein:
i) the hologram when viewed on angle affords the holographic image having parallax;
ii) the hologram when viewed increasingly off angle in a first direction, a second direction, and a third direction exhibits a decrease in brightness and visibility of the holographic image and the holographic image gradually fades away with the holographic layer appearing transparent as the hologram is tilted in each of these directions; and
iii) the hologram when viewed increasingly off angle in a fourth direction results in a monochrome surface suddenly appearing and at least partially masking the holographic image as the hologram is tilted increasingly in the fourth direction, said monochrome surface appearing and having a first color when viewed within a first range of viewing angles;
said method comprising the steps of:
(a) providing the hologram on an article to be authenticated;
(b) illuminating the hologram with light from a light source having a center wavelength and a spectral bandwidth, wherein the spectral bandwidth of the light overlaps the spectral bandwidth of the hologram; and
(c) establishing the article bearing the hologram to be authentic only if the holographic image and the monochrome surface are observed or detected to behave as described in i), ii), and iii) for the 1^{st}-4^{th} viewing directions.

12. The method of claim 11 wherein the first color is selected from the group consisting of red, gold, green, blue, and orange.

13. The method of claim 12 wherein the first color is red.

14. The method of claim 11 wherein the holographic element of claim 5 is used in place of the hologram and wherein the hologram eventually has the appearance of a monochrome surface corresponding to the color of the backing as the hologram is viewed increasingly off angle for each of the 1^{st}-4^{th} viewing directions.

15. The method of claim 14 wherein the color of the backing is black.

16. A method of fabricating a color wash hologram, the method comprising the steps of:
a) creating a holographic H2 image of at least one object in a first photosensitive layer by holographic imaging at a first wavelength λ1 to give a first exposed layer;
b) creating a holographic H2 image of a diffuser in a second photosensitive layer by holographic imaging at a second wavelength λ2 to give a second exposed layer;
c) placing the first and second exposed layers in proximity to one another;
d) placing a third photosensitive layer in contact with either the first exposed layer or the second exposed layer; and
e) exposing holographically the third photosensitive layer using a third wavelength λ3 through the first and second exposed layers to afford a third exposed layer containing the color wash hologram;
wherein λ1 and λ2 differ by at least 20 nanometers and λ3 lies between λ1 and λ2 and differs from λ1 by at least 5 nanometers.

17. The method of claim 16 wherein absolute value of (λ3−λ1) is less than absolute value of (λ3−λ2).

18. The method of claim 16 wherein (λ3−λ1) ranges from 5 nm to 35 nm.

19. The method of claim 16 wherein (λ2−λ3) ranges from 25 nm to 50 nm.
